(19) United States
(12) Patent Application Publication
(10) Pub. No.: US 2025/0223411 A1
(43) Pub. Date: Jul. 10, 2025

(54) FILM FORMATION METHOD, FILM FORMATION APPARATUS, AND METHOD OF MANUFACTURING ARTICLE

(71) Applicant: CANON KABUSHIKI KAISHA, Tokyo (JP)

(72) Inventors: TETSUJI OKADA, Saitama (JP); TOSHIKI ITO, Kanagawa (JP)

(21) Appl. No.: 19/007,984

(22) Filed: Jan. 2, 2025

(30) Foreign Application Priority Data
Jan. 9, 2024 (JP) 2024-001106

(51) Int. Cl. C08J 5/18; C08J 3/24

(52) U.S. Cl. CPC C08J 5/18; C08J 3/24

(57) ABSTRACT

A film formation method comprises an arrangement step of discretely arranging, as droplets, a curable composition that includes at least a polymerizable compound, a photopolymerization initiator, and a solvent on a shot region of a substrate, a liquid film formation step of causing each of the droplets discretely arranged on the shot region to combine with adjacent droplets so as to form a continuous liquid film on the shot region, and causing the solvent included in the liquid film to evaporate, a contact step of causing a predetermined region of a mold to come into contact with the liquid film, a main exposure step of curing the liquid film by irradiating curing light onto the liquid film after the contact, and a preliminary light irradiation step of irradiating preliminary light different from the curing light onto the liquid film so as to increase viscosity of the liquid film, wherein the preliminary light irradiation step is performed after the liquid film formation step and from before the contact step.

### BACKGROUND OF THE INVENTION

### Field of the Invention

The present invention relates to a film formation method, a film formation apparatus, and a method of manufacturing an article and the like.

### Description of the Related Art

In semiconductor devices and MEMS and the like, demands for miniaturization are increasing, and imprint technology is attracting attention as a fine processing technology. In imprint technology, a mold on which a fine concave-convex pattern is formed on a surface thereof is brought into contact with a curable composition supplied on a substrate, the curable composition is cured, and the pattern of the mold is transferred onto the substrate.

Japanese Patent No. 6632270 discloses a film formation method using imprint technology. In Japanese Patent No. 6632270, first, a cured product in a droplet state is discretely dropped onto a pattern formation region on a substrate. Next, the mold is brought into contact with the curable composition on the substrate.

Thereby, the droplets of the curable composition spread over the entire area of the gap between the substrate and the mold by capillary action. This phenomenon is called spreading. In addition, the curable composition is filled, by capillary action, into the concave portions that configure the pattern of the mold.

This phenomenon is called filling. During filling, after the curable composition is filled into marks formed on the mold, a position deviation between the marks formed on the mold and marks formed on the substrate is measured, and alignment of the substrate and the mold is performed.

When the alignment is completed, light is irradiated (main exposure is performed) onto the curable composition so as to cure the curable composition. Then, the mold is separated from the curable composition that has been cured on the substrate, and the pattern of the mold is formed onto the cured curable composition on the substrate.

In the aforementioned alignment, the higher the viscosity of the curable composition, the more difficult it becomes for the mold and the substrate, which are in contact with the curable composition, to vibrate relatively, thereby improving the accuracy of the alignment. Japanese Patent No. 6632270 discloses a technology for increasing the viscosity of the curable composition by performing preliminary irradiation of light onto at least a part of the curable composition on the substrate separately from the main exposure.

However, increasing the viscosity of the curable composition sufficiently by preliminary light irradiation requires time, resulting in a problem of decreased throughput. In particular, when oxygen is present in the atmosphere of the imprint space, polymerization inhibition of the curable composition occurs, requiring a long time to increase the viscosity.

In order to suppress the decrease in throughput as much as possible, a method of performing preliminary light irradiation as early as possible before alignment, for example, from before spreading, is conceivable. However, because the time required for spreading and filling increases when the viscosity of the curable composition increases before the droplets of the curable composition dispensed onto the substrate merge with each other, this results in the problem of further deterioration of throughput.

### SUMMARY OF THE INVENTION

A film formation method according to one aspect of the present invention comprises an arrangement step of discretely arranging, as droplets, a curable composition that includes at least a polymerizable compound, a photopolymerization initiator, and a solvent on a shot region of a substrate, a liquid film formation step of causing each of the droplets discretely arranged on the shot region to combine with adjacent droplets so as to form a continuous liquid film on the shot region, and causing the solvent included in the liquid film to evaporate, a contact step of causing a predetermined region of a mold to come into contact with the liquid film, a main exposure step of curing the liquid film by irradiating curing light onto the liquid film after the contact, and a preliminary light irradiation step of irradiating preliminary light different from the curing light onto the liquid film so as to increase the viscosity of the liquid film, wherein the preliminary light irradiation step is performed after the liquid film formation step and from before the contact step.

Further features of the present invention will become apparent from the following description of embodiments with reference to the attached drawings.

### BRIEF DESCRIPTION OF THE DRAWINGS

FIG. 1 is a diagram showing a configuration example of an imprint apparatus according to a First Embodiment.

FIG. 2 is a flowchart illustrating an example of a film formation method according to the First Embodiment.

FIG. 3A and FIG. 3B are diagrams illustrating examples of sub-regions of a substrate 3.

FIGS. 4A to 4D are diagrams for explaining an example of the liquid film formation process.

FIGS. 5A to 5C are diagrams for explaining an example of the film formation method according to the First Embodiment.

FIGS. 6A to 6E are diagrams explaining examples of alignment and the time taken for alignment.

FIG. 7 is a diagram showing a configuration example of an imprint apparatus IS according to a Second Embodiment.

FIG. 8 is a flowchart illustrating an example of a film formation method of the imprint apparatus IS according to the Second Embodiment.

FIGS. 9A to 9F are diagrams illustrating an example of a method for manufacturing an article.

### DESCRIPTION OF THE EMBODIMENTS

Hereinafter, with reference to the accompanying drawings, favorable modes of the present invention will be described using Embodiments. In each diagram, the same reference signs are applied to the same members or elements, and duplicate description will be omitted or simplified.

### First Embodiment

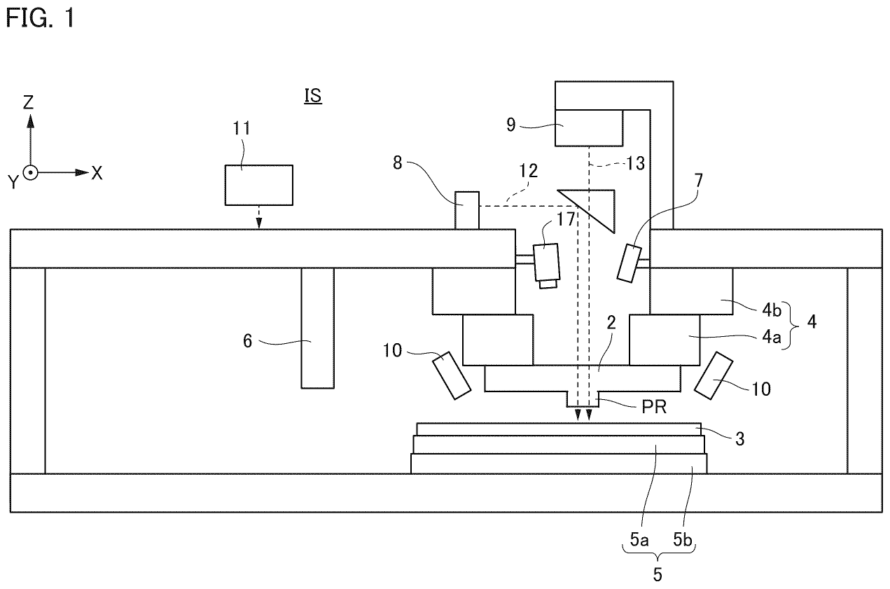

FIG. 1 is a diagram showing a configuration example of an imprint apparatus according to a First Embodiment. An imprint apparatus IS of the present embodiment is configured such that the viscosity of the curable composition, which is supplied onto the substrate, can be changed by irradiating light onto at least a part of the curable composition, prior to bringing the mold into contact with the curable composition on the substrate.

The imprint apparatus in the present embodiment functions as a film formation apparatus, and the film formation apparatus includes a planarization apparatus that forms a flat surface on the curable composition on the substrate by using a mold. In addition, the film formation method in the embodiments explained below includes a film formation method that uses a planarization apparatus.

In the present embodiment, directions are indicated in an XYZ coordinate system in which a direction parallel to the surface of the substrate is defined as the XY plane. A direction parallel to the X-axis in the XYZ coordinate system is defined as the X direction. A direction parallel to the Y-axis in the XYZ coordinate system is defined as the Y direction. A direction parallel to the Z-axis in the XYZ coordinate system is defined as the Z direction. A rotation around the X-axis is defined as θX. A rotation around the Y-axis is defined as θY. A rotation around the Z-axis is defined as θZ.

Control or driving with respect to the X-axis means control or driving with respect to a direction parallel to the X-axis. Control or driving with respect to the Y-axis means control or driving with respect to a direction parallel to the Y-axis. Control or driving with respect to the Z-axis means control or driving with respect to a direction parallel to the Z-axis. Positioning means controlling position, posture, or tilt. Alignment may include controlling the position, posture, or tilt of at least one of the substrate and the mold.

The imprint apparatus IS comprises a mold positioning unit 4 that is configured both to hold a mold 2 and to position the mold 2, and a substrate positioning unit 5 that is configured both to hold a substrate 3 and to position the substrate 3. In addition, the imprint apparatus IS is provided with a curable composition supply unit 6, an alignment measurement unit 7, a preliminary light irradiation unit 8, a curing light irradiation unit 9, a gas supply unit 10, an observation apparatus 17, and a control unit 11.

The mold 2 has, for example, an approximately rectangular outer shape and may be configured by a material capable of transmitting ultraviolet rays, such as quartz. The mold 2 has a pattern region PR on a surface facing the substrate 3. In the pattern region PR, a concave-convex pattern to be transferred to the curable composition on the substrate 3 is formed in a three-dimensional shape. The pattern region PR is also called a mesa, and is formed as a convex portion of several tens μm to several hundred μm so that portions of the mold 2 other than the pattern region PR do not come into contact with the substrate 3.

The substrate 3 is configured by, for example, a semiconductor (for example, silicon, compound semiconductor), glass, ceramics, metal, resin, and the like. The substrate 3 may have one or more layers on a base material. In this case, the base material is configured by, for example, a semiconductor, glass, ceramics, metal, resin, and the like. An adhesion layer may be provided on the substrate 3, as necessary, to improve adhesion between the curable composition and the substrate 3. A plurality of shot regions (imprint regions) are formed on the substrate 3.

The mold positioning unit 4 may include a mold holding unit 4a and a mold driving mechanism 4b. The mold holding unit 4a is configured to hold the mold 2 by, for example, a vacuum suction force, an electrostatic force, and the like. The mold driving mechanism 4b is a driving system configured to adjust the distance between the mold 2 and the substrate 3. The mold driving mechanism 4b is configured to drive (move) the mold 2 in the Z direction by driving the mold holding unit 4a.

The mold driving mechanism 4b is configured to include an actuator such as a linear motor or an air cylinder, and is configured to drive the mold holding unit 4a holding the mold 2. The mold driving mechanism 4b is configured to be capable of driving the mold 2 (mold holding unit 4a) with respect to a plurality of axes (for example, three axes that includes the Z-axis, θX-axis, and θY-axis).

To achieve high-precision positioning of the mold 2, the mold driving mechanism 4b may be configured to include a plurality of driving systems such as a coarse driving system and a fine driving system. In addition, the mold driving mechanism 4b may be configured to have a function of driving the mold 2 in the X direction, Y direction, and θZ direction, in addition to the Z direction, or a function of correcting the tilt of the mold 2.

The substrate positioning unit 5 may include a substrate holding unit 5a configured to hold the substrate 3 and a substrate driving mechanism 5b. The substrate holding unit 5a is configured to hold the substrate 3 by, for example, a vacuum suction force, an electrostatic force, and the like. The substrate driving mechanism 5b is configured to drive (move) the substrate 3 in the X direction and Y direction by driving the substrate holding unit 5a.

The substrate driving mechanism 5b is configured to include an actuator such as a linear motor or an air cylinder, and is configured to drive the substrate holding unit 5a that is configured to hold the substrate 3. The substrate driving mechanism 5b may be configured to drive the substrate 3 (substrate holding unit 5a) with respect to a plurality of axes (for example, three axes that includes the X-axis, Y-axis, and θZ-axis, preferably six axes that includes the X-axis, Y-axis, Z-axis, θX-axis, θY-axis, and θZ-axis).

The substrate driving mechanism 5b may be configured to include a plurality of driving systems such as a coarse driving system and a fine driving system. The substrate driving mechanism 5b may have a function of driving the substrate 3 in the Z direction and θZ direction, or may have a function of correcting the tilt of the substrate 3.

The curable composition supply unit 6 drops the curable composition onto the shot region of the substrate 3 by, for example, an inkjet method. The supply of the curable composition to the shot region of the substrate 3 is performed by ejecting the curable composition from a plurality of discharge ports by synchronizing with the driving of the substrate 3 in a state in which the substrate 3 is being driven by the substrate driving mechanism 5b.

It should be noted that the curable composition supply unit 6 has, for example, a plurality of discharge ports arranged in the Y direction, and is configured to simultaneously eject droplets of the curable composition onto the substrate 3 from the plurality of discharge ports such that the droplets of the curable composition are discretely arranged in the Y direction on the substrate 3.

In addition, the curable composition supply unit 6 can discretely arrange droplets in the X direction by intermittently ejecting droplets from the plurality of discharge ports while moving the substrate in the X direction. Droplets discretely arranged in the X direction and Y direction gradually combine with each other to form a continuous film of the curable composition.

The supply of the curable composition is sequentially and continuously performed for at least one or more shot regions, and thereafter, the imprint process is sequentially performed for each shot region to which the curable composition has been supplied.

The alignment measurement unit 7 detects alignment marks provided on the mold 2 and alignment marks provided on the substrate 3, and measures position deviation of the mold 2 and the substrate 3 in the X direction, Y direction, and around the θZ axis. The alignment measurement unit 7 is configured by a measurement light source for alignment mark detection, a camera, an optical system, and the like. In the present embodiment, in a case of simply referring to “position deviation” hereinafter, this shall refer to the position deviation between the shot region of the substrate 3 and the pattern region PR in the X direction, Y direction, and around the θZ axis.

The mold positioning unit 4 and the substrate positioning unit 5 drive the mold 2 or the substrate 3 so as to adjust the relative position, relative posture, and relative tilt between the mold 2 and the substrate 3 in the XY plane direction, and perform determination of the relative position between the mold 2 and the substrate 3. In the present embodiment, the substrate positioning unit 5 is controlled so as to reduce the position deviation measured by the alignment measurement unit 7.

Furthermore, the mold positioning unit 4 and the substrate positioning unit 5 change the position of the mold 2 and the substrate 3 in the Z direction, and drive the mold 2 or the substrate 3 so that the relative position, relative posture, and relative tilt between the mold 2 and the substrate 3 in the Z direction are adjusted. The adjustment of the relative position in the Z direction by the mold positioning unit 4 and/or the substrate positioning unit 5 includes both driving for bringing the curable composition on the substrate 3 into contact with the mold 2 and driving for separating the mold 2 from the cured curable composition (pattern of the cured product).

The preliminary light irradiation unit 8 has a light source and an illumination optical system for performing preliminary light irradiation, and is configured so as to be capable of irradiating a preliminary light 12 onto the substrate 3. The preliminary light 12 that the preliminary light irradiation unit 8 irradiates includes light of a wavelength that causes a curing reaction of the curable composition.

The preliminary light irradiation unit 8 is configured to be capable of adjusting the illuminance, irradiation distribution, and the like by using, for example, a DMD (Digital Micromirror Device). The DMD includes a plurality of mirror elements and can adjust the irradiation region by individually controlling the surface direction of the plurality of mirror elements. The preliminary light 12 is irradiated onto the curable composition applied on the substrate 3, although with an exposure amount that is insufficient to completely cure the curable composition.

The curing light irradiation unit 9 cures the curable composition by supplying or irradiating a curing light 13 for curing of the curable composition (for example, infrared rays, visible light, ultraviolet rays, far ultraviolet rays, X-rays, charged particle beams such as electron beams, or radiation). Specifically, the curing light irradiation unit 9 irradiates light (main exposure) via the mold 2 in a state in which the curable composition on the shot region of the substrate 3 is in contact with the pattern region PR of the mold 2 and has filled the pattern region PR.

Accordingly, a pattern consisting of a cured product of the curable composition is formed on the substrate. In the present embodiment, the curing light irradiation unit 9 has, for example, a light source that emits curing light 13 for curing the curable composition. In addition, the curing light irradiation unit 9 may include an optical element for adjusting the curing light emitted from the light source to an appropriate light amount in the imprint process.

The gas supply unit 10 is configured to supply a replacement gas (not shown) and functions to replace the atmosphere of the space that is irradiated by the preliminary light irradiation unit 8 with the replacement gas. The replacement gas is, for example, an inert gas such as helium or carbon dioxide.

Because polymerization inhibition of the curable composition occurs when oxygen is present in the atmosphere surrounding the curable composition, a long time is required to increase the viscosity of the curable composition by the preliminary light 12. Therefore, in the present embodiment, when irradiating the curable composition with the preliminary light 12, the gas supply unit 10 replaces the atmosphere surrounding the curable composition with an inert gas. Thereby, the time required to increase the viscosity is shortened.

The observation apparatus 17 is an image capturing device, such as a CCD camera or a CMOS camera, and is configured to acquire shape information of the curable composition on the substrate 3 as image information.

The control unit 11 is configured to control the entirety (operation) of the imprint apparatus 1. The control unit 11 may be configured by, for example, a PLD such as an FPGA, an ASIC, a general-purpose computer such as a CPU in which a program is incorporated, or a combination of all or part of these.

FPGA is an abbreviation for Field Programmable Gate Array, PLD is an abbreviation for Programmable Logic Device, and ASIC is an abbreviation for Application Specific Integrated Circuit.

The control unit 11 functions as a control means configured to control operation of each part of the entire apparatus based on a computer program stored in a memory serving as a storage medium. It should be noted that the control unit 11 may be provided within the imprint apparatus or may be provided outside the imprint apparatus.

The curable composition in the present embodiment is a curable composition for inkjet and includes at least a polymerizable compound A, a photopolymerization initiator B, and a solvent C. The curable composition in the present embodiment may further include a non-polymerizable compound.

The polymerizable compound A is a compound that reacts with polymerization factors generated from the photopolymerization initiator B and forms a film consisting of a high molecular compound by chain reaction. As such a polymerizable compound, for example, a radical polymerizable compound is used.

The polymerizable compound A may be configured by only one type of polymerizable compound or may be configured by a plurality of types of polymerizable compounds. For radical polymerizable compounds, (meth)acrylic compounds, styrene compounds, vinyl compounds, allyl compounds, fumaric compounds, maleic compounds, and the like are used.

In the film formation method of the present embodiment, because the process of droplets of the curable composition discretely arranged on the substrate combining to form a continuous liquid film takes from several milliseconds to several hundred seconds, a liquid film formation process described below becomes necessary. In the liquid film formation process, while the solvent C is evaporated, the polymerizable compound A is prevented from evaporating.

Therefore, it is preferable that the boiling points of all polymerizable compounds, which may be included in a plurality of types, under atmospheric pressure are 250° C. or higher, more preferably 300° C. or higher, and even more preferably 350° C. or higher.

The photopolymerization initiator B included in the curable composition is a compound configured to sense light of a predetermined wavelength and generate the aforementioned polymerization factors. Specifically, the photopolymerization initiator is a polymerization initiator configured to generate radicals by the curing light 13.

The photopolymerization initiator of the present embodiment may be configured by only one type of photopolymerization initiator or may be configured by a plurality of types of photopolymerization initiators. As the polymerization initiator, for example, acylphosphine oxide compounds and the like are used.

The solvent C included in the curable composition is a solvent having a boiling point of 80° C. or higher and lower than 250° C. under atmospheric pressure. For the solvent C, a solvent is used in which the polymerizable compound and photopolymerization initiator dissolve, such as an alcohol-based solvent, a ketone-based solvent, an ether-based solvent, an ester-based solvent, a nitrogen-containing solvent, and the like.

The solvent may be used either as one type alone or in combination of two or more types. When the boiling point of the solvent C under atmospheric pressure is lower than 80° C., because the evaporation rate in the liquid film formation process described below becomes too fast, the solvent may evaporate before the droplets of the curable composition combine with each other, potentially preventing the droplets of the curable composition from combining.

In addition, when the boiling point of the solvent under atmospheric pressure is 250° C. or higher, evaporation of the solvent C becomes insufficient in the evaporation process described below, and there is a possibility that the solvent C may remain in the cured product of the curable composition.

In the present embodiment, in a case in which the entire curable composition is set as 100% by volume, the content of the solvent C is set to 5% by volume or more and 95% by volume or less. This is because when the content of the solvent C is less than 5% by volume, under conditions in which a substantially continuous liquid film is obtained, a thin film cannot be obtained after evaporation of the solvent.

In addition, if the content of the solvent C exceeds 95% by volume, even if droplets are dropped as densely as possible by the inkjet method, a thick film cannot be obtained after the evaporation of the solvent.

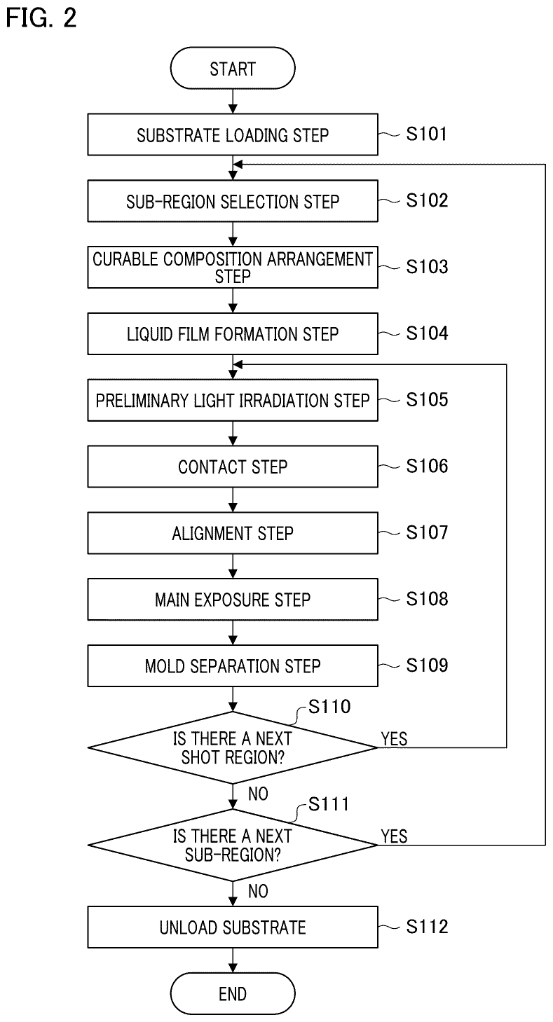

Next, the film formation method of the present embodiment will be explained. FIG. 2 is a flowchart showing an example of the film formation method according to the First Embodiment, and an example of a method for forming patterns on a plurality of shot regions of the substrate 3 is shown.

The operations of each step in the flowchart of FIG. 2 are performed sequentially by the CPU or the like serving as a computer in the control unit 11 executing a computer program stored in memory. However, an explanation with respect to the processes of loading the mold into the mold holding unit 4a and unloading the mold 2 from the mold holding unit 4a is omitted.

After holding the mold by loading the mold into the mold holding unit 4a, in step S101 (substrate loading step), the control unit 11 controls a substrate transfer apparatus (not shown) so as to load the substrate 3 into the substrate holding unit 5a and hold the substrate 3.

In step S102 (sub-region selection step), the control unit 11 selects, from among all shot regions of the substrate 3 held in the substrate holding unit 5a, a sub-region consisting of at least one or more shot regions.

For each selected sub-region, processing of steps S103 to S110 described below is performed. That is, for each sub-region, at least the arrangement process through to the main exposure process described below is performed. In the present embodiment, a sub-region is, for example, a predetermined plurality of shot regions arranged along the direction (X-axis direction in the present embodiment) connecting the curable composition supply unit 6 for arranging droplets on the shot region and the preliminary light irradiation unit 8 for irradiating preliminary light.

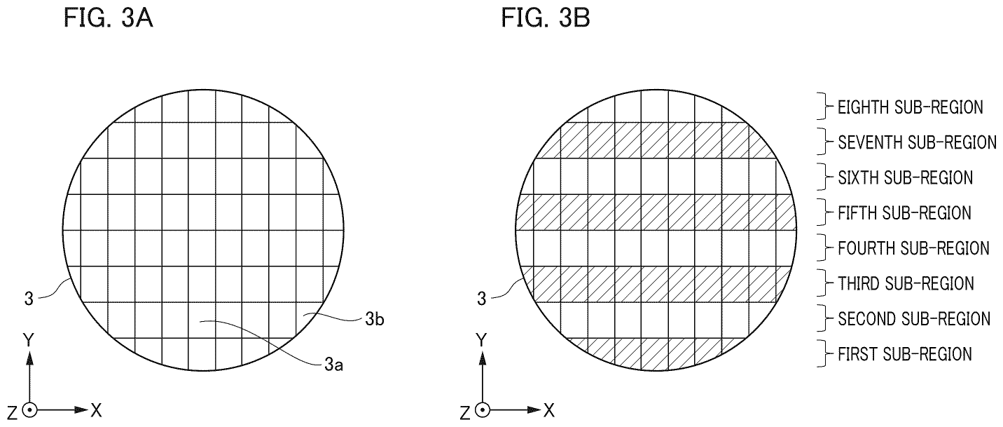

FIG. 3A and FIG. 3B are diagrams illustrating examples of sub-regions of the substrate 3, wherein FIG. 3A shows the layout of a plurality of shot regions of the substrate 3. As shown in FIG. 3A, typically, with respect to the circular substrate 3, each individual shot region 3a has a rectangular shape except for the shot regions 3a located at the outer peripheral portion.

Here, a plurality of shot regions arranged in the X direction are defined as one sub-region. FIG. 3B shows an example wherein the plurality of shot regions are divided into 8 rows of sub-regions (first to eighth sub-regions), each row arranged in the X direction. In step S102, for example, the fourth sub-region is selected.

The range of shot regions that can be selected as a sub-region is not limited thereto, and one shot region alone may be selected as a sub-region, or only partial shot regions 3b may be selected as a sub-region, or all shot regions may be selected as a sub-region.

In step S103 (curable composition arrangement step), droplets of the curable composition are discretely arranged by simultaneously ejecting the droplets from a plurality of discharge ports of the curable composition supply unit 6 onto the sub-region selected in step S102. Here, step S103 functions as an arrangement step serving to discretely arrange, as droplets, a curable composition that includes at least a polymerizable compound, a photopolymerization initiator, and a solvent on a shot region of the substrate.

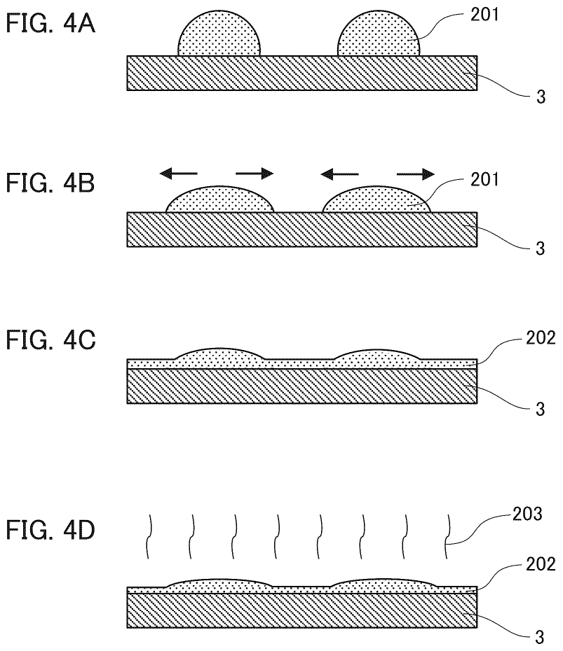

FIGS. 4A to 4D are diagrams for explaining an example of the liquid film formation process, and FIG. 4A schematically shows droplets 201 discretely arranged on the substrate 3.

The droplets 201 of the curable composition are preferably arranged densely on regions of the substrate 3 facing areas where concave and convex portions configuring the pattern region PR of the mold 2 are densely present, and sparsely on regions of the substrate 3 facing areas where concave and convex portions configuring the pattern of the mold 2 are sparsely present. Thereby, the film of the curable composition formed on the substrate 3 is controlled so as to have a uniform thickness regardless of the density of the pattern of the mold 2.

Step S104 (liquid film formation step) is a step in which each of the droplets 201 discretely arranged on the substrate combines with adjacent droplets 201 to form a continuous liquid film, and thereafter, the solvent C included in the liquid film is evaporated. That is, in step S104, each of the droplets discretely arranged on the shot region is caused to combine with adjacent droplets so as to form a continuous liquid film on the shot region, and the solvent included in the liquid film is caused to evaporate.

Here, a continuous liquid film refers to a state in which all droplets 201 within the shot region are at least combined with adjacent droplets, and preferably, a state in which the entire shot region is continuously covered with the curable composition.

In the liquid film formation step, the droplets 201 of the curable composition spread on the substrate 3, as schematically shown in FIG. 4B. Thereby, the selected sub-region of the substrate 3 is continuously covered with the curable composition.

Here, the average film thickness is defined as the value obtained by dividing the total volume of droplets of the curable composition dropped onto one shot region by the area of the shot region. In a case in which the average initial liquid film thickness is 80 nm or more, as schematically shown in FIG. 4C, droplets of the curable composition may combine with each other on the substrate to form a continuous liquid film 202.

In addition, in a case in which the average initial liquid film thickness is 89 nm or more, the surface of the liquid film may become flat. A liquid film having an average initial liquid film thickness of 80 nm or more can be obtained by arranging droplets of the curable composition with a volume of 1.0 pL or more at a density of 80 droplets/mm² or more. Similarly, a liquid film with an average initial liquid film thickness of 89 nm can be obtained by arranging droplets of the curable composition having a volume of 1.0 pL or more at a density of 89 droplets/mm².

Furthermore, in step S104, the solvent 203 included in the liquid film 202 is evaporated, as schematically shown in FIG. 4D. After step S104, when the total volume of components other than the solvent is set as 100% by volume, the amount of solvent 203 remaining in the liquid film 202 should preferably be 10% by volume or less. In a case in which the amount of remaining solvent exceeds 10% by volume, there is a possibility that mechanical properties of the cured film may decrease.

In step S104 (liquid film formation step), the atmosphere gas surrounding the substrate 3 may be ventilated for the purpose of accelerating evaporation of the solvent 203.

Step S104 (liquid film formation step) is set to, for example, 0.1 seconds or more. In a case in which the time is shorter than 0.1 seconds, the combination of the droplets of the curable composition becomes insufficient, and a substantially continuous liquid film is not formed.

In step S104 (liquid film formation step), when the solvent C evaporates, a substantially continuous liquid film 202 consisting of the polymerizable compound A and the photopolymerization initiator B remains. The average remaining liquid film thickness of the substantially continuous liquid film 202 from which the solvent has evaporated becomes thinner than the liquid film 202 in FIG. 4C by the amount of solvent C that has evaporated.

In step S105 (preliminary light irradiation step), the control unit 11 controls the preliminary light irradiation unit 8, irradiates the preliminary light 12 onto the liquid film 202 of the curable composition on the sub-region of the substrate 3, and increases the viscosity of the liquid film 202.

It should be noted that step S105 (preliminary light irradiation step) is a step for increasing the viscosity of the liquid film by irradiating preliminary light different from the curing light in the main exposure onto the liquid film, wherein this step is performed after the liquid film formation step and from before the contact step.

In step S105, a masking member may be arranged such that the preliminary light does not leak to other sub-regions. Alternatively, instead of using such a masking member, the preliminary light irradiation unit 8 may use a laser light source and a DMD to obtain sharp light-shielding characteristics at the edge of the shot region. In addition, in step S105 of the Present Embodiment, the gas supply unit 10 replaces the atmosphere surrounding the curable composition with an inert gas in order to shorten the time for irradiating the preliminary light 12.

It should be noted that steps S103 to S105 may be processes that collectively process all shot regions of the sub-region, or may be processes that sequentially process each individual shot region of the sub-region.

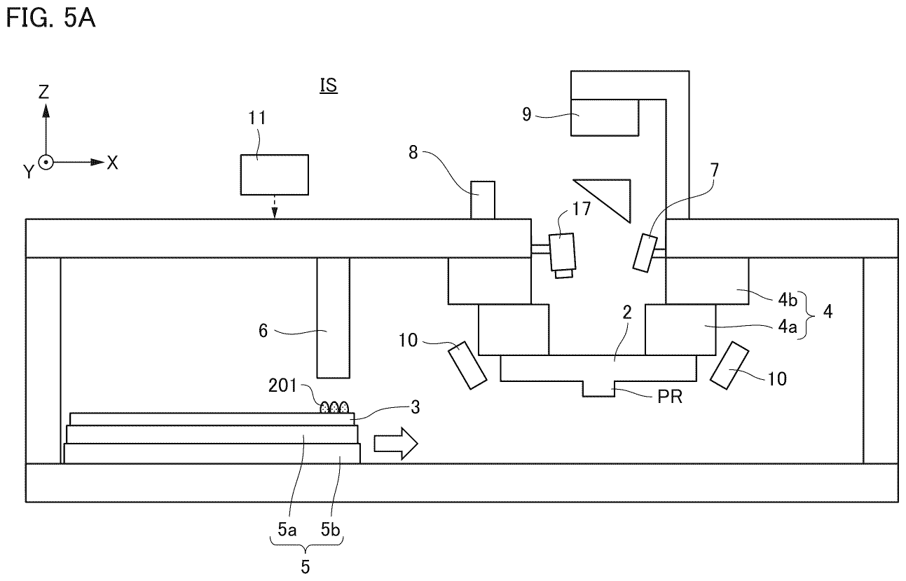

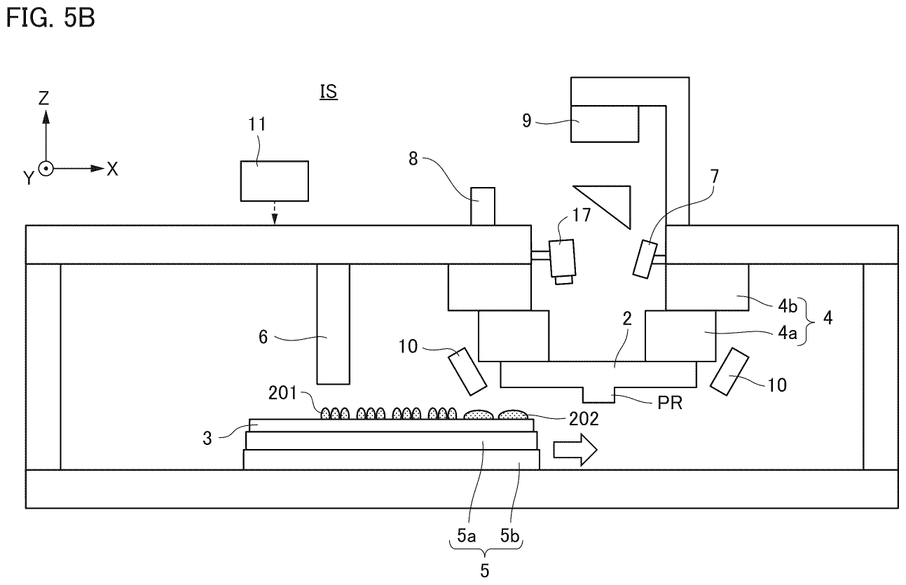

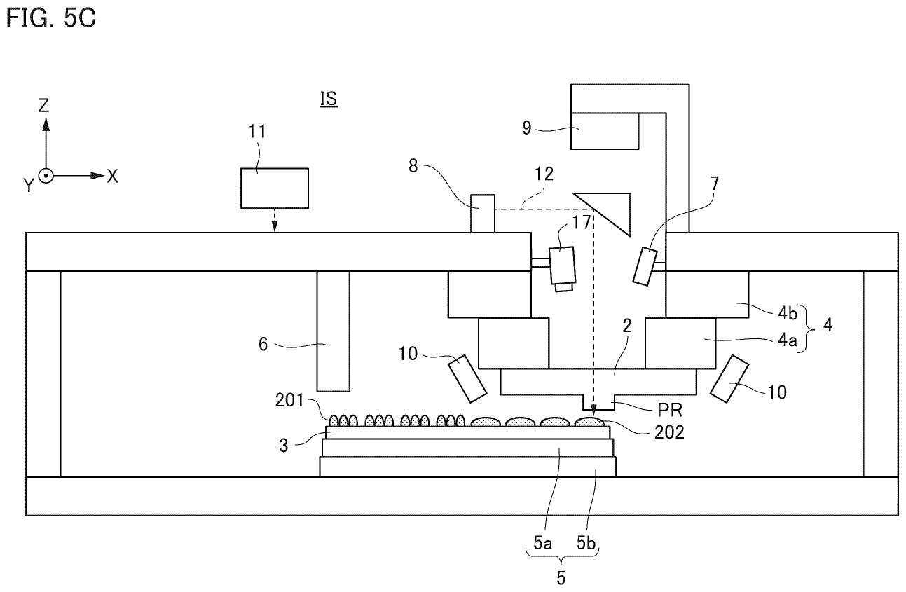

FIGS. 5A to 5C are diagrams for explaining an example of the film formation method according to the First Embodiment. As shown in FIG. 5A, the control unit 11 controls the substrate positioning unit 5 (substrate 3) so as to move the substrate positioning unit 5 in the X direction at a constant speed while sequentially supplying a plurality of droplets 201 to each shot region of the sub-region from a plurality of discharge ports arranged in the Y direction of the curable composition supply unit 6.

That is, at a certain position in the X direction, a plurality of droplets 201 are simultaneously supplied from a plurality of discharge ports arranged in the Y direction, and then, after moving in the X direction, a plurality of droplets 201 are again simultaneously supplied from a plurality of discharge ports arranged in the Y direction. By repeating such an operation, droplets are discretely arranged in the X direction and Y direction.

At this time, as shown in FIG. 5B, for shot regions among the sub-region for which step S103 serving as the curable composition arrangement step has been completed, step S104 serving as the liquid film formation step is sequentially performed, and formation of the liquid film 202 is initiated by evaporating a part of the solvent C from the droplets 201. In addition, during this time, the shot regions on which the liquid film 202 has been formed move toward the irradiation position of the preliminary light irradiation unit 8.

It should be noted that, in order to sufficiently evaporate the solvent C, the speed of the substrate positioning unit 5 should preferably be set smaller than the value obtained by dividing the distance from the curable composition supply unit 6 to the irradiation position of the preliminary light 12 by the time required for the solvent to evaporate.

Next, as shown in FIG. 5C, at the timing when the shot region to which the curable composition has been supplied reaches the irradiation position of the preliminary light below the preliminary light irradiation unit 8, in step S105 (preliminary light irradiation step), the preliminary light irradiation unit 8 irradiates the preliminary light 12 onto the corresponding shot region.

Here, the method of determining the start time of step S105 (preliminary light irradiation step) will be explained. Because increasing viscosity of the curable composition before a continuous liquid film is formed leads to increased time required for spreading and filling, step S105 is set such that step S105 starts after step S104 (liquid film formation step) has been completed in the target shot region.

In addition, if the start time of step S105 is excessively delayed, the liquid film 202 may spread too much, causing the edge of the liquid film 202 to exceed the edge of the target shot region, which may result in defective chips created by the imprint process.

That is, in the Present Embodiment, in the target shot region, control is performed such that the time interval from discretely arranging the droplets 201 on the substrate to irradiating the preliminary light onto the liquid film 202 falls within a predetermined target range.

This predetermined target range can be obtained, for example, by prior evaluation. Specifically, first, droplets 201 are dropped onto a test sample substrate from the curable composition supply unit 6. Then, after a certain time has elapsed, the curing light 13 is irradiated so as to cause the curable composition to cure, and thereafter, the shape of the curable composition is observed and evaluated.

By repeating this evaluation while changing the time interval from dropping of the droplets 201 to curing, how the shape of the droplets of the curable composition changes with the passage of time can be evaluated, and the target range of time duration for step S104 (liquid film formation step) can be obtained.

In addition, as another method for determining the start time of step S105, in step S105, the combination state of adjacent droplets of the droplets 201 discretely arranged on the target shot region is acquired by the observation apparatus 17, and the timing for irradiating the preliminary light 12 may be determined based on this combination state.

Specifically, for example, the timing for irradiating the preliminary light 12 onto the liquid film 202 may be determined based on the ratio of the area of the shot region covered by the liquid film 202. That is, the combination state may be related to, for example, the ratio of the shot region covered by the liquid film.

Alternatively, the combination state may be related to the distance from the outer periphery of the liquid film 202 to the outer periphery of the corresponding shot region, and the preliminary light 12 may be irradiated onto the liquid film 202 at the timing at which the above distance becomes equal to or less than a predetermined distance. In this manner, it is possible to prevent excessive expansion of the liquid film.

It should be noted that step S105 (preliminary light irradiation step) may be performed in parallel with step S106 (contact step) or step S107 (alignment step) to be described below, and by starting step S106 or step S107 during the implementation of step S105, throughput can be improved.

In step S106 (contact step), the control unit 11 drives the mold positioning unit 4 in the Z direction and causes the predetermined region (pattern region PR) of the mold 2 to come into contact with the continuous liquid film 202 on the substrate 3. In the Present Embodiment, because in step S104 (liquid film formation step) the curable composition becomes a continuous liquid film 202 from which the solvent C has been removed, the volume of gas entrapped between the mold 2 and the substrate 3 becomes small.

Therefore, although the viscosity of the curable composition increases due to step S105 (preliminary light irradiation step), the spreading and filling of the curable composition in the contact step are completed quickly.

In step S107 (alignment step), based on the position deviation between the mold 2 and the substrate 3 measured by the alignment measurement unit 7, the substrate positioning unit 5 is driven so as to eliminate the position deviation. That is, in step S107 (alignment step), the mold or the substrate is moved so as to eliminate the position deviation between the shot region and the pattern region of the mold.

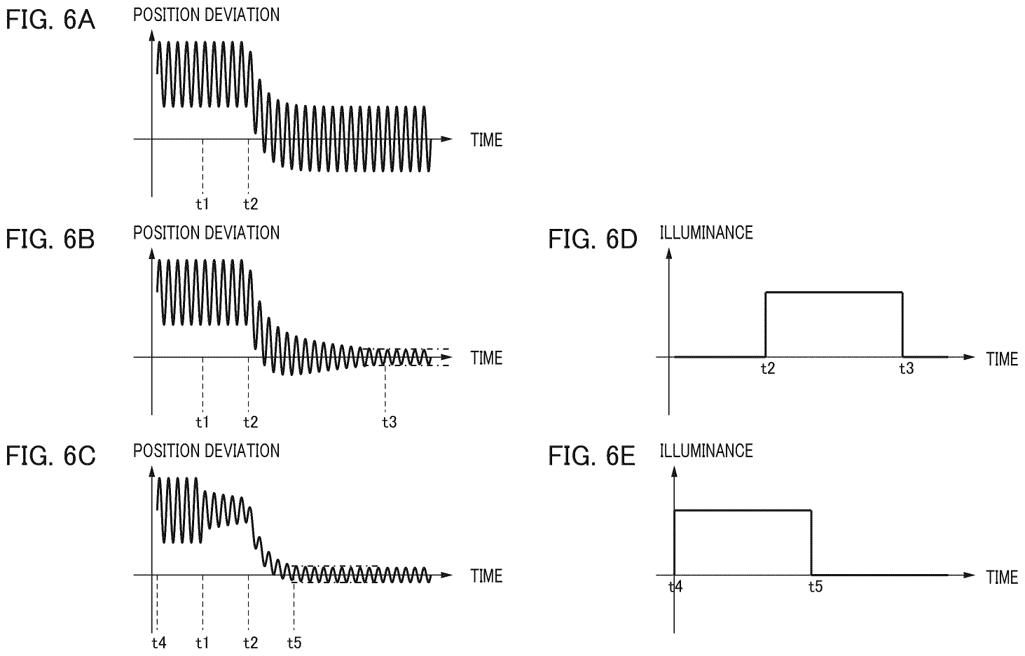

Here, FIGS. 6A to 6E are diagrams for explaining examples of alignment and the time taken for alignment, and with reference to FIG. 6, an explanation will be provided with respect to the alignment between the substrate 3 and the mold 2 and the time taken for this alignment. In FIGS. 6A to 6C, graphs are shown with time on the horizontal axis and positional deviation between the mold 2 and the substrate 3 in the X direction on the vertical axis.

FIG. 6A shows a graph explaining the position deviation in a case in which step S105 (preliminary light irradiation step) is omitted for comparison with the Present Embodiment. The time t1 in the graph represents the start time of step S106 (contact step), and the time t2 represents the start time of step S107 (alignment step).

The vibration component shown in the graph is a component that may be generated by vibration of the imprint apparatus 1. In a case in which the viscosity of the curable composition is low, this vibration may remain even after a sufficient time has elapsed after the start of step S107 (alignment step), as shown in FIG. 6A. This is because the substrate positioning unit 5 cannot fully follow high-frequency vibrations due to factors such as the measurement frequency of the alignment measurement unit and the responsiveness of the substrate positioning unit 5.

FIG. 6B shows a graph for comparison with the Present Embodiment, wherein step S105 (preliminary light irradiation step) is implemented simultaneously with the start of step S107 (alignment step), as is the case with conventional technology. Additionally, FIG. 6D shows a graph in which time is on the horizontal axis and the illuminance of the preliminary light 12 is plotted on the vertical axis for the case shown in FIG. 6B.

The time t3 in the graph indicates the time at which the position deviation has sufficiently attenuated, that is, the end time of the preliminary light irradiation step (alignment step). Here, the time t3−time t2 represents the time required for the preliminary light irradiation unit 8 to irradiate the preliminary light 12 onto the liquid film 202 and sufficiently increase the viscosity of the liquid film 202. Because the illuminance value in FIG. 6D has an upper limit determined by optical design constraints and light source lifespan, it is not possible to shorten the time t3−time t2 to less than a predetermined time.

The example in FIG. 6B shows that alignment accuracy improves after the start of preliminary light irradiation when compared to the example in FIG. 6A. The improvement occurs because in a state wherein the mold is in contact with the curable composition, when the viscosity of the curable composition increases, relative vibration between the mold and substrate becomes more difficult.

FIG. 6C is a graph of position deviation in a case in which the Present Embodiment is applied. FIG. 6E shows a graph in which time is on the horizontal axis and the illuminance of the preliminary light 12 is on the vertical axis in the case of FIG. 6C. In the Present Embodiment, step S105 (preliminary light irradiation step) is started before the start time t1 of step S106 (contact step).

t4 indicates the start time of step S105 (preliminary light irradiation step), and t5 indicates the end time of step S105 (preliminary light irradiation step). The illuminance in FIG. 6E is equal to the illuminance in FIG. 6D, and the time duration for irradiating the preliminary light 12 (t5−t4) in FIG. 6E is equal to the time duration for irradiating the preliminary light (t3−t2) in FIG. 6D. That is, the amount of preliminary light 12 irradiation in FIG. 6E is equal to the amount of preliminary light 12 irradiation in FIG. 6D.

As shown in FIG. 6C, in the Present Embodiment, the amplitude of position deviation is reduced at time t1, that is, at the start of the contact step. This reduction occurs because the viscosity of the liquid film 202 has increased due to the irradiation of preliminary light 12 before step S106 (contact step), thereby making relative vibration between the pattern region PR in contact with the liquid film 202 and the substrate 3 more difficult.

Furthermore, FIG. 6C shows that positioning accuracy equivalent to that at the end time t3 of the preliminary light irradiation step in FIG. 6B is obtained at the end time t5 of the preliminary light irradiation step. That is, FIG. 6C shows that the Present Embodiment can end the alignment step at an earlier time compared to the conventional technology shown in FIG. 6B. This means that it is possible to move to the next step earlier, thereby increasing throughput.

In step S108 (main exposure step), the control unit 11 controls the curing light irradiation unit 9 so as to cure the liquid film 202 by irradiating the curing light 13 onto the liquid film 202. That is, in step S108 (main exposure step), after the predetermined region of the mold is brought into contact with the liquid film, the curing light is irradiated onto the liquid film to cure the liquid film.

In step S109 (mold separation step), the control unit 11 drives the mold positioning unit 4 so as to separate the mold 2 from the substrate 3. By separating the cured film having the pattern from the pattern region PR, a cured film having a pattern that is an inversion of the fine pattern of the pattern region PR is obtained on the substrate 3.

In step S110, the control unit 11 determines whether there is a next shot region to which the curable composition has been supplied. In a case in which there is a next shot region, the process returns to step S105, and the imprint process is repeated for the next shot region. It should be noted that although the time elapsed from step S104 becomes larger for later shot regions, the number of shots within one sub-region is set so that the maximum spread of the liquid film is within a predetermined range.

If it is determined in step S110 that there is no next shot region, the process proceeds to step S111. In step S111, it is determined as to whether there are any sub-regions in which the supply of curable composition has not been completed. In a case in which there is a sub-region in which the supply of curable composition has not been completed, the process returns to step S102, and the next sub-region is selected.

In step S112 (substrate unloading step), the control unit 11 controls the substrate transfer apparatus so as to unload the substrate 3 from the substrate holding unit 5a, and ends the flow of FIG. 2.

In this manner, the film formation method of the First Embodiment increases the viscosity of the curable composition by irradiating preliminary light after the liquid film formation step and before the contact step. Thereby, the end time of the positioning step can be shortened, and both high alignment accuracy and high throughput can be achieved.

### Second Embodiment

Hereinafter, an imprint apparatus and film formation method according to a Second Embodiment will be explained. Matters not mentioned in the Second Embodiment follow the First Embodiment. In the First Embodiment, the shot regions of the substrate were divided into sub-regions, and the liquid film formation step and preliminary light irradiation step were performed sequentially for the shot regions within the sub-region.

In contrast, in the Second Embodiment, the liquid film formation step is performed after arranging the curable composition on all shot regions of the substrate, and thereafter, the preliminary light irradiation step is performed.

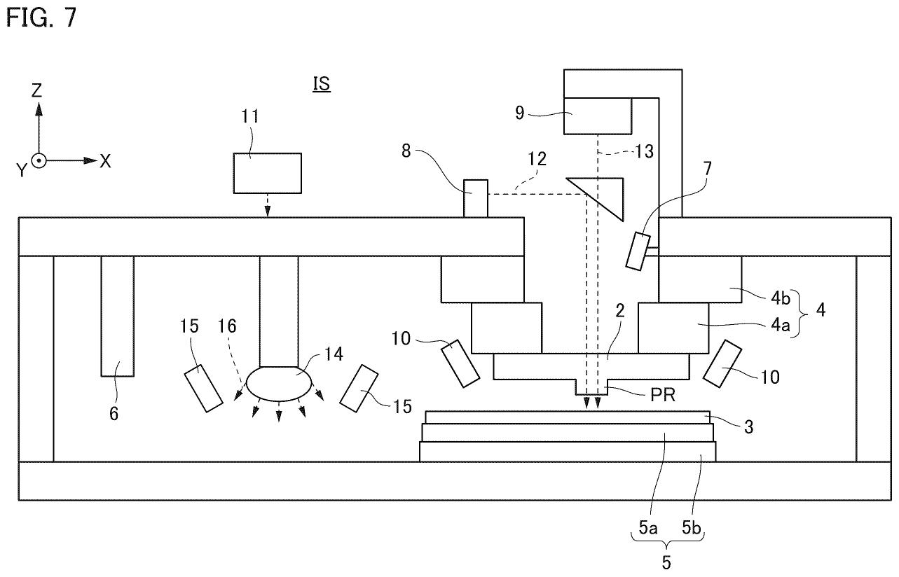

FIG. 7 is a diagram showing a configuration example of the imprint apparatus IS according to the Second Embodiment. The imprint apparatus IS is provided with a second preliminary light irradiation unit 14 and a gas supply unit 15.

The imprint apparatus IS further includes a mold positioning unit 4 that is configured to hold the mold 2 and to position the mold 2, and a substrate positioning unit 5 that is configured to hold the substrate 3 and to position the substrate 3. In addition, the imprint apparatus IS is provided with a curable composition supply unit 6, an alignment measurement unit 7, a preliminary light irradiation unit 8, a curing light irradiation unit 9, a gas supply unit 10, and a control unit 11. Because components other than the second preliminary light irradiation unit 14 are equivalent to components in the First Embodiment, explanations thereof are omitted.

The second preliminary light irradiation unit 14 is arranged at a position close to the substrate 3, unlike the preliminary light irradiation unit 8 positioned far from the substrate 3 above the Z-axis of the mold 2. Thereby, this arrangement provides advantages in optical design, making possible both the widening of the irradiation range of the preliminary light and increasing the output thereof.

In addition, the second preliminary light irradiation unit 14 can collectively irradiate a preliminary light 16 onto the curable composition of all of the plurality of shot regions of the substrate. In addition, the second preliminary light irradiation unit 14 may have a configuration that can vary the irradiation amount in the radial direction of the substrate 3 or a configuration that can vary the irradiation amount for each shot region of the substrate 3. Thereby, differences in viscosity of the curable composition between shot regions can be reduced.

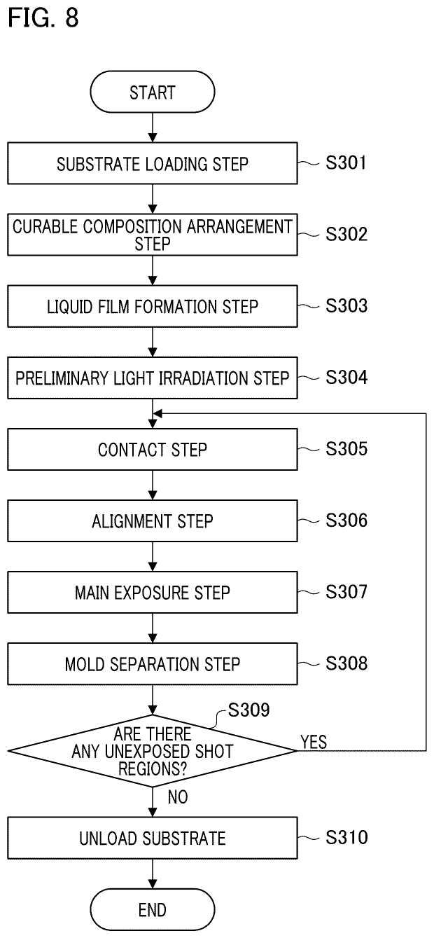

FIG. 8 is a flowchart illustrating an example of a film formation method of the imprint apparatus IS according to the Second Embodiment. However, an explanation of loading the mold 2 into the mold holding unit 4a and unloading the mold 2 from the mold holding unit 4a is omitted.

It should be noted that the operations of each step in the flowchart of FIG. 8 are performed sequentially by the CPU or the like serving as a computer in the control unit 11 executing a computer program stored in memory.

After holding the mold by loading the mold into the mold holding unit 4a, in step S301 (substrate loading step), the control unit 11 controls a substrate transfer apparatus (not shown), and loads and holds the substrate 3 in the substrate holding unit 5a.

In step S302 (curable composition arrangement step), droplets 201 of the curable composition are discretely arranged from the curable composition supply unit 6 onto all shot regions of the substrate 3.

Step S303 (liquid film formation step) is a step in which the solvent C is evaporated to form a liquid film after the droplets of the curable composition combine with each other. As explained in the First Embodiment, in a case in which the average initial liquid film thickness is 80 nm or more, the droplets of the curable composition may combine with each other on the substrate to form a continuous liquid film 202. In addition, in a case in which the average initial liquid film thickness is 89 nm or more, the surface of the liquid film may become flat.

Furthermore, in step S303 (liquid film formation step), the solvent C included in the liquid film 202 is evaporated. In step S303, for the purpose of accelerating the evaporation of the solvent C, a baking process may be performed to heat the substrate 3 and the curable composition, or the atmosphere gas surrounding the substrate 3 may be replaced by, for example, the gas supply unit 15. The baking process can be performed by using a heating device such as a hot plate.

After the liquid film formation step has been completed for all shot regions on the substrate by step S303, the process moves to step S304 (preliminary light irradiation step), wherein the control unit 11 controls the second preliminary light irradiation unit 14 so as to irradiate the preliminary light 16 onto the liquid film 202 on all shot regions of the substrate 3. At this time, to shorten the time for irradiating the preliminary light 16, the gas supply unit 15 may replace the atmosphere surrounding the curable composition with an inert gas.

In addition, in step S304, in order to make the viscosity of the liquid film 202 uniform on all shot regions, the second preliminary light irradiation unit 14 changes the irradiation amount of the preliminary light 16 for each shot region. For example, in a case in which the ratio of replacement with inert gas by the gas supply unit 15 has a distribution in the radial direction of the substrate 3, the irradiation amount of the preliminary light 16 is given a distribution in the radial direction of the substrate 3.

That is, according to the concentration distribution of the inert gas, the irradiation amount is distributed in the radial direction of the substrate 3 in such a manner that the irradiation amount of the preliminary light 16 becomes smaller as the concentration becomes higher.

In step S305 (contact step), the control unit 11 drives the mold positioning unit 4 and causes the pattern region PR of the mold 2 to come into contact with the continuous liquid film 202 on the substrate 3. In the Present Embodiment, because the curable composition becomes a continuous liquid film 202 from which the solvent C has been removed in step S303 (liquid film formation step), the volume of gas entrapped between the mold 2 and the substrate 3 becomes small.

Therefore, even if the viscosity of the curable composition increases in step S304 (preliminary light irradiation step), the spreading and filling of the curable composition in the contact step is completed quickly.

In step S306 (alignment step), the substrate positioning unit 5 is driven so as to eliminate the position deviation based on the position deviation between the mold 2 and the substrate 3 measured by the alignment measurement unit 7. In the Present Embodiment, because the preliminary light irradiation step is completed before step S305 (contact step), the position deviation attenuates more quickly compared to a case in which the preliminary light irradiation step is started after step S305 (contact step). Therefore, the time for step S306 (alignment step) can be shortened.

It should be noted that the irradiation of the preliminary light 16 may be performed not only in step S304 (preliminary light irradiation step) but also in step S306 (alignment step) by using the preliminary light irradiation unit 8. For example, the increase in viscosity of the curable composition by the preliminary light 16 in step S304 may be limited to a predetermined level, and in step S306 (alignment step), the preliminary light 12 may be irradiated until the amplitude of the position deviation observed by the alignment measurement unit 7 is reduced to below a target level.

That is, the preliminary light may be irradiated by using only the second preliminary light irradiation unit 14 without using the preliminary light irradiation unit 8, and the viscosity control may be optimized by combining the operation of the second preliminary light irradiation unit 14 and the preliminary light irradiation unit 8. By operating the second preliminary light irradiation unit 14 and the preliminary light irradiation unit 8 in combination, it is possible to prevent the viscosity of the curable composition from increasing more than necessary before step S305 (contact step).

It should be noted that if the viscosity of the curable composition is too high, the high viscosity may hinder the filling of the curable composition into the pattern region of the mold 2. In addition, there may be cases in which the irradiation of the preliminary light 16 in step S304 need only be performed on some of the shot regions among all shot regions of the substrate 3.

For example, because the replacement of the atmosphere surrounding the liquid film 202 with an inert gas by the gas supply unit 10 may be easy depending on the position of the shot regions on the substrate, oxygen inhibition during curing of the curable composition is less likely to occur. Therefore, the viscosity of the curable composition may increase in a short time merely by irradiating the preliminary light 12 in step S306 (alignment step).

For such shot regions, irradiation of the preliminary light 16 from before step S305 (contact step) is not always necessary. In contrast, in the case of partial shot regions 3b, for example, replacement with an inert gas is not easy, and therefore oxygen inhibition during curing of the curable composition is more likely to occur, and because the viscosity is less likely to increase, the irradiation amount of the preliminary light 16 may be increased.

That is, it is desirable to change the irradiation amount (light amount or irradiation time) of the preliminary light according to the shot region. Alternatively, for example, the preliminary light 16 may be irradiated only onto partial shot regions 3b. That is, among all shot regions on the substrate, the preliminary light irradiation step may be performed only on some shot regions, such as partial shot regions, after the liquid film formation step and before the contact step.

In step S307 (main exposure step), the control unit 11 is configured to cure the liquid film 202 by controlling the curing light irradiation unit 9 so as to irradiate the curing light 13 onto the liquid film 202.

In step S308 (mold separation step), the control unit 11 separates the mold 2 from the substrate 3 by driving the mold positioning unit 4. By separating the cured film having the pattern from the pattern region PR, a cured film having a pattern that is an inversion of the fine pattern of the pattern region PR is obtained on the substrate 3.

In step S309, a determination is made as to whether there are any unexposed shot regions. In a case in which there are unexposed shot regions, the process returns to step S305, and the imprint is repeated for those shot regions.

In step S310 (substrate unloading step), the control unit 11 controls the substrate transfer apparatus, unloads the substrate 3 from the substrate holding unit 5a, and ends the flow of FIG. 8.

In this manner, the film formation method of the Second Embodiment increases the viscosity of the curable composition after the liquid film formation step and before the contact step. Thereby, the end time of the positioning step can be shortened, and both high alignment accuracy and high throughput can be realized.

### Embodiment of Article Manufacturing Method

The pattern of the cured product formed by using the imprint apparatus is used permanently for at least some part of various articles, or temporarily when manufacturing various articles. Articles refer to electric circuit elements, optical elements, MEMS, recording elements, sensors, or molds, and the like.

Examples of electric circuit elements include volatile or non-volatile semiconductor memories such as DRAM, SRAM, flash memory, and MRAM, and semiconductor elements such as LSI, CCD, image sensors, and FPGA. Examples of molds include molds for imprinting and the like.

The pattern of the cured product serves either as a permanent constituent member for at least some of the constituent members of the above-mentioned articles or serves temporarily as a resist mask. After etching or ion implantation and the like are performed in the substrate processing step, the resist mask is removed.

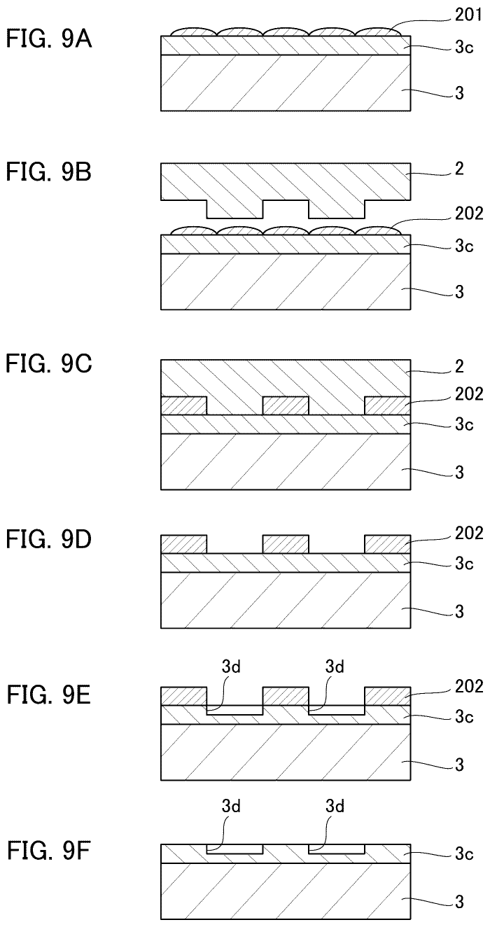

Next, a method of manufacturing an article will be explained. FIGS. 9A to 9F are diagrams illustrating an example of a method for manufacturing an article. In step (A) of FIG. 9, a substrate 3 such as a silicon substrate with a processed material 3c such as an insulator formed on the surface thereof is prepared, and thereafter, droplets 201 of imprint material serving as a curable composition are applied to the surface of the processed material 3c by an inkjet method or the like. Here, a state is shown wherein a plurality of droplets 201 of imprint material are applied onto the substrate.

In step (B) of FIG. 9, the mold 2 for imprinting is positioned facing the liquid film 202 of imprint material on the substrate, wherein the side of the mold 2 on which the concave-convex pattern is formed is directed towards the liquid film 202. In step (C) of FIG. 9, the substrate 3 on which the liquid film 202 of imprint material is formed is brought into contact with the mold 2, and pressure is applied. The liquid film 202 of imprint material is filled into the gap between the mold 2 and the processed material 3c. In this state, when light is irradiated as energy for curing via the mold 2, the liquid film 202 of imprint material is cured.

In step (D) of FIG. 9, after curing the liquid film 202 of imprint material, when the mold 2 and the substrate 3 are separated, a pattern of the cured product of the liquid film 202 of imprint material is formed on the substrate 3. In this pattern of the cured product, the concave portion of the mold corresponds to the convex portion of the cured product, and the convex portion of the mold corresponds to the concave portion of the cured product. That is, the concave-convex pattern of the mold 2 becomes transferred to the liquid film 202 of imprint material.

By the film formation method shown in steps (A) to (D) of FIG. 9, a substrate having a formed film is created.

In step (E) of FIG. 9, when etching is performed using the pattern of the cured product as an etching resistant mask, among portions of the surface of the processed material 3c, those portions in which the cured product does not exist or remains thin are removed, and these portions become grooves 3d.

In step (F) of FIG. 9, when the pattern of the cured product is removed, an article having grooves 3d formed on the surface of the processed material 3c can be obtained. Here, steps (E) to (F) of FIG. 9 function as a manufacturing step for manufacturing an article from the substrate by processing the substrate having the formed film. It should be noted that although in this example the pattern of the cured product is removed, the pattern of the cured product may be used without removal after processing as, for example, an interlayer insulating film included in semiconductor elements, that is, as a constituent member of an article.

While the present invention has been described with reference to exemplary embodiments, it is to be understood that the invention is not limited to the disclosed exemplary embodiments. The scope of the following claims is to be accorded the broadest interpretation to encompass all such modifications and equivalent structures and functions.

In addition, as a part or the whole of the control according to the embodiments, a computer program realizing the function of the embodiments described above may be supplied to the film formation apparatus and the like through a network or various storage media. Then, a computer (or a CPU, an MPU, or the like) of the film formation apparatus and the like may be configured to read and execute the program. In such a case, the program and the storage medium storing the program configure the present invention.

In addition, the present invention includes those realized using at least one processor or circuit configured to perform functions of the embodiments explained above. For example, a plurality of processors may be used for distribution processing to perform functions of the embodiments explained above.

This application claims the benefit of priority from Japanese Patent Application No. 2024-001106, filed on Jan. 9, 2024, which is hereby incorporated by reference herein in its entirety.

What is claimed is:

1. A film formation method comprising:
an arrangement step of discretely arranging, as droplets, a curable composition that includes at least a polymerizable compound, a photopolymerization initiator, and a solvent on a shot region of a substrate;
a liquid film formation step of causing each of the droplets discretely arranged on the shot region to combine with adjacent droplets so as to form a continuous liquid film on the shot region, and causing the solvent included in the liquid film to evaporate;
a contact step of causing a predetermined region of a mold to come into contact with the liquid film;
a main exposure step of curing the liquid film by irradiating curing light onto the liquid film after the contact; and
a preliminary light irradiation step of irradiating preliminary light different from the curing light onto the liquid film so as to increase the viscosity of the liquid film, wherein the preliminary light irradiation step is performed after the liquid film formation step and from before the contact step.

2. The film formation method according to claim 1, further comprising an alignment step of moving the mold or the substrate so as to eliminate position deviation between the shot region and a pattern region of the mold.

3. The film formation method according to claim 2, wherein the preliminary light irradiation step and the alignment step are performed in parallel.

4. The film formation method according to claim 1, wherein the preliminary light irradiation step and the contact step are performed in parallel.

5. The film formation method according to claim 1, wherein a time interval from discretely arranging the droplets on the shot region to irradiating the preliminary light onto the liquid film is controlled so as to be within a predetermined target range.

6. The film formation method according to claim 1, wherein a combination state between the droplets discretely arranged on the shot region and adjacent droplets is observed, and a timing for irradiating the preliminary light is determined based on the combination state.

7. The film formation method according to claim 6, wherein the combination state relates to a ratio of the shot region covered by the liquid film.

8. The film formation method according to claim 6, wherein the combination state relates to a distance from an outer periphery of the liquid film to an outer periphery of the shot region.

9. The film formation method according to claim 1, further comprising a sub-region selection step of selecting a sub-region consisting of at least one or more of the shot regions from the substrate,
wherein the arrangement step to the main exposure step are performed for each of the sub-regions.

10. The film formation method according to claim 9, wherein the sub-region is a plurality of the shot regions arranged along a direction connecting a curable composition supply unit that is configured to arrange the droplets on the shot region and a preliminary light irradiation unit that is configured to irradiate the preliminary light.

11. The film formation method according to claim 9, wherein the liquid film formation step is sequentially performed for each of the shot regions in the sub-region for which the arrangement step has been completed.

12. The film formation method according to claim 1, wherein the method transitions to the preliminary light irradiation step after the liquid film formation step has been completed for all of the shot regions on the substrate.

13. The film formation method according to claim 1, wherein the preliminary light irradiation step is performed only for some of the shot regions among all of the shot regions on the substrate after the liquid film formation step and from before the contact step.

14. A method of manufacturing an article, the method comprising:
a manufacturing step of manufacturing an article from the substrate by processing the substrate having a film formed by the film formation method according to claim 1.

15. A film formation apparatus comprising:
a curable composition supply unit configured to discretely arrange, as droplets, a curable composition that includes at least a polymerizable compound, a photopolymerization initiator, and a solvent on a shot region of a substrate;
a mold positioning unit configured to cause each of the droplets discretely arranged on the shot region to combine with adjacent droplets so as to form a continuous liquid film on the shot region, and after causing the continuous liquid film to be formed, cause a predetermined region of a mold to come into contact with the liquid film;
a curing light irradiation unit configured to perform main exposure of curing the liquid film by irradiating curing light onto the liquid film after the contact; and
a preliminary light irradiation unit configured to irradiate preliminary light different from the curing light onto the liquid film so as to increase viscosity of the liquid film, wherein the preliminary light irradiation unit is configured to irradiate the preliminary light after the liquid film is formed and from before the contact with the mold.
